(19) United States
(12) Patent Application Publication
(10) Pub. No.: US 2024/0036811 A1
(43) Pub. Date: Feb. 1, 2024

(54) Fast Method for Calculating Digital Volume Approximate Value in Audio Recording or Playing

(71) Applicant: Fuzhou ZHUO, Fujian (CN)

(72) Inventor: Fuzhou ZHUO, Fujian (CN)

(21) Appl. No.: 18/378,154

(22) Filed: Oct. 10, 2023

(30) Foreign Application Priority Data
Nov. 14, 2022 (CN) 202211419730.6

(51) Int. Cl. G06F 3/16

(52) U.S. Cl. CPC G06F 3/165

(57) ABSTRACT

Disclosed by the present invention is a fast method for calculating a digital volume approximate value in audio recording or playing, which includes a volume comparison and extraction module, a volume fading module, a volume gear roughing module, a volume approximate correction module and a volume summation module. Theoretical calculation of the errors proves that the errors of the present invention are acceptable in various application products, and in addition, the solving algorithm is intuitive in principle structure and rapid in solving process. The method has the advantages of low computing resource consumption and high universality.

### TECHNICAL FIELD

The present invention belongs to the field of audio technology, and particularly relates to a fast method for calculating digital volume approximate value in audio recording or playing.

### BACKGROUND OF THE INVENTION

A plurality of music recording and playing systems, video recording and playing systems and teleconferencing systems require visual access to the presence of audio signals, the volume size and other information, so that users may troubleshoot and control the systems on site in a better way. As for an audio processing and analysis module, received audio data is mostly binary data obtained by ADC sampling, which has a linear relation with a voltage of the audio volume. In most instances, the volume size is reflected on the user interface as a dB value. Theoretically, a logarithmic operation is necessary for conversion from the binary data to the dB value, which is difficult to realize or requires more resources and time in some audio data analysis systems (e.g., FPGA system).

### BRIEF SUMMARY OF THE INVENTION

The object of the present invention is to provide a method for a fast method for calculating digital volume approximate value in audio recording or playing, which has the advantages of short solution process and low computing resource consumption. Although it is an approximate solving algorithm, the difference between the actually solved and output result and the theoretical value is fractional, so the method is suitable for various occasions without strict accuracy requirements for volume indication, such as music recording and playing systems, video recording and playing systems and teleconferencing systems.

The present invention provides a fast method for calculating digital volume approximate value in audio recording or playing, which includes the following steps:
step 1, inputting an audio signal which is output by an audio ADC (Analog-to-Digital Converter) and has a linear relation with an audio voltage into a volume comparison and extraction module;
step 2, the volume comparison and extraction module calculates a maximum volume in the audio signal output by the audio ADC, compares the maximum volume output by the audio ADC with an output value of a volume fading module, and outputs the larger one thereof to the volume fading module and a volume gear roughing module as an output value, separately;
step 3, the volume fading module subtracts a cancellation value from the output value of the volume comparison and extraction module to conduct hysteresis processing on the volume cancellation, and outputs the processing result to the input end of the volume comparison and extraction module; supposing the cancellation time is 0.3 s to 0.5 s, the maximum value possibly output by the audio ADC is the maximum volume, a minimum volume is 0, and an ADC sampling rate is a system preset value, then the cancellation value that changes with the ADC sampling rate is calculated by the following formula (1):

$$Cancellation value = \frac{Maximum volume - Minimum volume}{ADC sampling rate * Cancellation time} \qquad ( 1 )$$

step 4, defining the maximum volume as 0 dB, circularly shifting the output value of the volume comparison and extraction module to the left until the highest bit is 1, after the circular shift left, directly outputting the result value to a volume approximate correction module, subtracting 6 dB from the output value of the volume comparison and extraction module each time a circular left shift is done, that is, a cumulative calculation result is obtained by subtracting the product of the number of circular left shifts and 6 dB from the output value of the volume comparison and extraction module, and then directly outputting the cumulative calculation result to a volume summation module after the circular shift left;
step 5, the volume approximate correction module corrects the output value of the volume gear roughing module within a more precise dB value interval than that of the volume gear roughing module, only remains three bits of MSB-1, MSB-2 and MSB-3, and respectively records the values of the three bits as b1, b2 and b3 to obtain a corrected result of 3*b1+1*b2+1*b3, and the volume approximate correction module outputs the corrected result to the volume summation module; and
step 6, the volume summation module sums over the output dB values of the volume gear roughing module and the volume approximate correction module, and then outputs a digital volume approximate value as the result.

The present invention provides a computer-readable storage medium using computer programming, a fast program for calculating digital volume approximate value is stored on the computer-readable storage medium, so that a computer is able to execute the steps of the fast method for calculating digital volume approximate value in audio recording or playing when the program is executed on the computer.

As an approximate solving algorithm, calculation errors are introduced in the processing process of the volume gear roughing module and the volume approximate correction module, theoretical calculation of the errors proves that the errors of the present invention are acceptable in various application products, and in addition, the solving algorithm is intuitive in principle structure and rapid in solving process. The method has the advantages of low computing resource consumption and high universality, and may be applied to development and application of various platforms such as an FPGA, a DSP, an ARM and a PC.

### BRIEF DESCRIPTION OF THE DRAWINGS

FIG. 1 is a schematic diagram of the working principle of the present invention.

The present invention will be further described below in conjunction with accompanying drawings and specific embodiments.

### DETAILED DESCRIPTION OF THE INVENTION

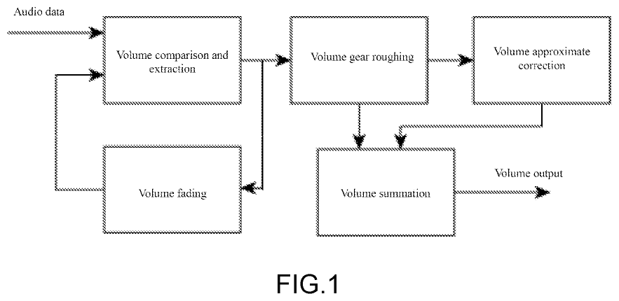

As shown in FIG. 1, the first embodiment of the present invention relates to a device for fast calculating a digital volume approximate value in audio recording or playing, which mainly includes a volume comparison and extraction module, a volume fading module, a volume gear roughing module, a volume approximate correction module and a volume summation module, where,

the volume comparison and extraction module inputs an audio signal which is output by an audio ADC and has a linear relation with an audio voltage and an output result of the volume fading module, calculates a maximum volume in the audio signal output by the audio ADC, compares the maximum volume in the audio signal output by the audio ADC with the output value of the volume fading module, and outputs the larger one thereof to the volume fading module and the volume gear roughing module as an output value, separately. The audio data is an alternating current signal, the volume size recognized by human ears is the maximum volume effect in a short period of time, and the time precision discriminated by perception is far less than the audio sampling interval. Hence, the volume comparison and extraction module outputs the larger one of a current audio ADC sampling value and the output value of the audio fading module.

The volume fading module, to meet the time precision discriminated by human auditory perception and visual perception, needs to conduct hysteresis processing on the volume cancellation. The module plays an equivalent role to an RC discharge circuit in an analog circuit, to be specific, performing the hysteresis processing on the volume cancellation by subtracting a cancellation value from the output value of the volume comparison and extraction module, and outputting the processing result to the input end of the volume comparison and extraction module. Normally, the cancellation time is set to 0.3 s to 0.5 s, the maximum value (i.e., full scale) possibly output by the audio ADC is the maximum volume, a minimum volume is 0 (i.e., mute), an ADC sampling rate varies with the systems and is substantially set to a nominal value (e.g., 44.1 KHz, 48 KHz or 96 KHz) in the audio and video field, then the cancellation value that changes with the ADC sampling rate is calculated by the following formula (1):

$$Cancellation value = \frac{Maximum volume - Minimum volume}{ADC sampling rate * Cancellation time} \qquad ( 1 )$$

For instance, supposing the cancellation time is 0.5 s, the maximum volume is 2²³, which is the maximum value possibly output by the audio ADC of the system, the minimum volume is 0, the ADC sampling rate is 48 KHz, and then substituting the above values into the formula (1) to get the cancellation value changing with the ADC sampling rate:

$$Cancellation value = \frac{Maximum volume - Minimum volume}{ADC sampling rate * Cancellation time} = \frac{{2}^{33} - 0}{48000 SPS * 0.5 S} \approx 350 \qquad ( 2 )$$

The volume gear roughing module defines the maximum volume as 0 dB, circularly shifts the output value of the volume comparison and extraction module to the left until the highest bit is 1, after the circular shift left, directly outputs the result value to the volume approximate correction module, subtracts 6 dB from the output value of the volume comparison and extraction module each time a circular left shift is done, that is, a cumulative calculation result is obtained by subtracting the product of the number of circular left shifts and 6 dB from the output value of the volume comparison and extraction module, and then directly outputs the cumulative calculation result to the volume summation module after the circular shift left.

The volume approximate correction module corrects the output value of the volume gear roughing module within a more precise dB value interval than that of the volume gear roughing module, only remains three bits of MSB-1, MSB-2 and MSB-3, and respectively records the values of the three bits as b1, b2 and b3 to obtain a corrected result of 3*b1+1*b2+1*b3, and the volume approximate correction module outputs the corrected result to the volume summation module; and the term “more precise” as used herein refers to the output precision of 1 dB of the module, in view of the output precision of 6 dB of the volume gear roughing module.

The volume summation module sums over the output dB values of the volume gear roughing module and the volume approximate correction module, and then outputs a digital volume approximate value as the result.

The second embodiment of the present invention relates to a fast method for calculating digital volume approximate value in audio recording or playing, which includes the following steps:

Step 1, an audio signal which is output by an audio ADC and has a linear relation with an audio voltage is input into a volume comparison and extraction module.

Step 2, the volume comparison and extraction module calculates a maximum volume in the audio signal output by the audio ADC, compares the maximum volume output by the audio ADC with an output value of a volume fading module, and outputs the larger one thereof to the volume fading module and a volume gear roughing module as an output value, separately.

Step 3, the volume fading module subtracts a cancellation value from the output value of the volume comparison and extraction module to conduct hysteresis processing on the volume cancellation, and outputs the processing result to the input end of the volume comparison and extraction module. Normally, the cancellation time is set to 0.3 s to 0.5 s, the maximum value (i.e., full scale) possibly output by the audio ADC is the maximum volume, a minimum volume is 0 (i.e., mute), an ADC sampling rate varies with the systems and is substantially set to a nominal value (e.g., 44.1 KHz, 48 KHz or 96 KHz) in the audio and video field, then the cancellation value that changes with the ADC sampling rate is calculated by the following formula (1):

$$Cancellation value = \frac{Maximum volume - Minimum volume}{ADC sampling rate * Cancellation time} \qquad ( 1 )$$

Step 4, the maximum volume is defined as 0 dB, the output value of the volume comparison and extraction module is circularly shifted to the left until the highest bit is 1, after the circular shift left, the result value is directly output to a volume approximate correction module, the output value of the volume comparison and extraction module is decremented by 6 dB each time a circular left shift is done, that is, a cumulative calculation result is obtained by subtracting the product of the number of circular left shifts and 6 dB from the output value of the volume comparison and extraction module, and then the cumulative calculation result is directly output to a volume summation module after the circular shift left.

Step 5, the volume approximate correction module corrects the output value of the volume gear roughing module within a more precise dB value interval than that of the volume gear roughing module, only remains three bits of MSB-1, MSB-2 and MSB-3, and respectively records the values of the three bits as b1, b2 and b3 to obtain a corrected result of 3*b1+1*b2+1*b3, and the volume approximate correction module outputs the corrected result to the volume summation module.

Step 6, the volume summation module sums over the output dB values of the volume gear roughing module and the volume approximate correction module, and then outputs a digital volume approximate value as the result.

The second embodiment is a method implementation corresponding to the first embodiment and can be implemented in cooperation with the first embodiment. The related technical details mentioned in the first embodiment are still valid in this embodiment, so they are not described here to reduce duplicating work. Accordingly, the related technical details mentioned in this embodiment can also be applied in the first embodiment.

The third embodiment of the present invention relates to a computer-readable storage medium using computer programming, a fast program for calculating digital volume approximate value is stored on the computer-readable storage medium, so that a computer is able to execute the steps in the above-mentioned second embodiment when the program is executed on the computer.

The output error of the present invention is theoretically calculated, and derived using an indication interval from 0 dB to −60 dB of the common commercially available equipment:

(1) Regarding error introduced by a volume gear roughing module

The number of circular left shifts in the volume gear roughing module is supposed to be N, the error introduced is:

Δ₁=6·N−20 log₁₀2^{N}=N(6−20·log₁₀2)≈N·0.0206<0.206N<10

(2) The errors introduced by a volume approximate correction module are shown in the table below.

| | | Corrected value of | |
|---|---|---|---|
| Input value of | Theoretically | the present | |
| module | calculated dB value | invention | Error |
| 000 | 0 | 0 | 0 |
| 001 | 0.023 | 1 | 0.977 |
| 010 | 0.938 | 1 | 0.062 |
| 011 | 1.766 | 2 | 0.234 |
| 100 | 2.522 | 3 | 0.478 |
| 101 | 3.217 | 4 | 0.783 |
| 110 | 3.861 | 4 | 0.139 |
| 111 | 4.343 | 5 | 0.657 |

As shown in the table, the fact that the resulted corrected values of the present invention are larger than the theoretically calculated values is consistent with the actual situation that not all low-bit ADC data not involved in the operation of the present invention are null, so the actual error is less than the maximum value of 0.977 in Table 1.

(3) Regarding an integrated error of the present invention

The output result of the present invention is the sum of the outputs of the volume gear roughing module and the volume approximate correction module, so its theoretical error is ∇_{z}<0.977+0.206=1.113 dB. In view of the fact that the audio volume output is mostly a perceptual indication of the volume size and is not highly precise, the present invention has application significance.

It should be noted that all implementations of the present invention can be realized with software, hardware, firmware and so forth. The instruction codes can be stored in any type of computer-accessible memory (e.g., permanent or modifiable, volatile or nonvolatile, solid or non-solid, fixed or removable medium), irrespective of the software, hardware or firmware where the present invention is realized. Again, the memory can be a PAL (Programmable Array Logic), an RAM (Random Access Memory), a PROM (Programmable Read-Only Memory), an ROM (Read Only Memory), an EPROM (Erasable Programmable Read-Only Memory), a disk, an optical disk, a DVD (Digital Versatile Disc) and so forth.

It should be noted that all units/modules mentioned in all implementations of the present invention are logical units/modules. Physically, a logic unit can be a physical unit, a part of a physical unit or a combination of a plurality of physical units. The key to solve the technical problems proposed by the present invention does not lie in the physical realization mode of these logic units but the combination of functions realized by these logical units. In addition, in order to highlight the inventive part of the present invention, the above-mentioned implementations of the present invention do not introduce units that are not closely related to solving the technical problems proposed by the present invention, which is not indicative of non-existence of other units in the above-mentioned implementations.

It should be noted that, the terms “comprises,” “includes,” or any other variation of Claims and Description of the disclosure are intended to cover a non-exclusive inclusion, such that a process, method, article or apparatus that comprises a list of elements does not include only those elements but may include other elements not expressly listed or inherent to such process, method, article or apparatus. An element preceded by “comprises a” or “comprises an” does not, without further constraints, preclude the existence of additional identical elements in the process, method, article or apparatus that comprises the element.

Although the present invention has been illustrated and described with reference to some preferred embodiments thereof, it should be appreciated that those skilled in the art can make various modifications and alterations in form and detail without departing from the spirit and scope of the disclosure.

What is claimed is:

1. A fast method for calculating digital volume approximate value in audio recording or playing, characterized by comprising the following steps:
step 1, inputting an audio signal which is output by an audio ADC (Analog-to-Digital Converter) and has a linear relation with an audio voltage into a volume comparison and extraction module;
step 2, the volume comparison and extraction module calculates a maximum volume in the audio signal output by the audio ADC, compares the maximum volume output by the audio ADC with an output value of a volume fading module, and outputs the larger one thereof to the volume fading module and a volume gear roughing module as an output value, separately;
step 3, the volume fading module subtracts a cancellation value from the output value of the volume comparison and extraction module to conduct hysteresis processing on the volume cancellation, and outputs the processing result to the input end of the volume comparison and extraction module; supposing the cancellation time is 0.3 s to 0.5 s, the maximum value possibly output by the audio ADC is the maximum volume, a minimum volume is 0, and an ADC sampling rate is a system preset value, then the cancellation value that changes with the ADC sampling rate is calculated by the following formula (1):
$$Cancellation value = \frac{Maximum volume - Minimum volume}{ADC sampling rate * Cancellation time} \qquad ( 1 )$$
step 4, defining the maximum volume as 0 dB, circularly shifting the output value of the volume comparison and extraction module to the left until the highest bit is 1, after the circular shift left, directly outputting the result value to a volume approximate correction module, subtracting 6 dB from the output value of the volume comparison and extraction module each time a circular left shift is done, that is, a cumulative calculation result is obtained by subtracting the product of the number of circular left shifts and 6 dB from the output value of the volume comparison and extraction module, and then directly outputting the cumulative calculation result to a volume summation module after the circular shift left;
step 5, the volume approximate correction module corrects the output value of the volume gear roughing module within a more precise dB value interval than that of the volume gear roughing module, only remains three bits of MSB-1, MSB-2 and MSB-3, and respectively records the values of the three bits as b1, b2 and b3 to obtain a corrected result of 3*b1+1*b2+1*b3, and the volume approximate correction module outputs the corrected result to the volume summation module; and
step 6, the volume summation module sums over the output dB values of the volume gear roughing module and the volume approximate correction module, and then outputs a digital volume approximate value as the result.

2. A computer-readable storage medium using computer programming,
characterized in that a fast program for calculating digital volume approximate value is stored on the computer-readable storage medium, so that a computer is able to execute the steps of the fast method for calculating digital volume approximate value in audio recording or playing according to claim 1 when the program is executed on the computer.
